(19) United States
(12) Patent Application Publication
(10) Pub. No.: US 2017/0337987 A1
(43) Pub. Date: Nov. 23, 2017

(54) SELF-TESTING A STORAGE DEVICE VIA SYSTEM MANAGEMENT BUS INTERFACE

(71) Applicant: Western Digital Technologies, Inc., San Jose, CA (US)

(72) Inventors: Gurjit CHADHA, Irvine, CA (US); Michael ROTHBERG, Foothill Ranch, CA (US); George SNEED, Irvine, CA (US)

(21) Appl. No.: 15/673,562

(22) Filed: Aug. 10, 2017

Related U.S. Application Data
(63) Continuation of application No. 14/688,979, filed on Apr. 16, 2015.

(51) Int. Cl. G11C 29/56; G11B 27/00; G11C 29/06; G11C 29/12

(52) U.S. Cl. CPC G11C 29/56; G11C 29/1201; G11B 27/00; G11C 29/06; G11C 2029/5602

(57) ABSTRACT

A system and method are provided for self-testing one or more digital data storage drives. In particular, a drive tester system connects to the one or more digital data storage drives via a standard two-wire interface, such as a system management bus interface or an I²C interface. The drive tester system performs a self-test on the on more digital data storage drives via the standard two-wire interface. The self-test of the digital data storage drive includes a burn-in and endurance test.

### CROSS-REFERENCE TO RELATED APPLICATIONS

This application is a continuation application of co-pending U.S. patent application Ser. No. 14/688,979, filed on Apr. 16, 2015, which herein is incorporated by reference.

### FIELD

The embodiments relate generally to testing of a storage device via system management bus (SMB) interface.

### BACKGROUND

Typical solid state drive (SSD) manufacturing process begins with surface-mount technology (SMT) mounting of electronic components on the printed circuit (PC) board(s). Each PC board is then board-level verified by “interconnection testing” using techniques such as in-circuit test (ICT) or flying probe testing, before the subassemblies are assemble into a drive. Such a drive is typically in the form of a Peripheral Component Interconnect Express (PCIe) Card Edge or a small form factor (SFF) “drive”.

Once the drive is assembled, the drive needs to be initialized before board-level testing can begin at the factory. An “out of band” interface, not dependent on the device's firmware, is typically used to initialize the drive at the factory. A typical “out of band” interface used for the initialization is a universal asynchronous receiver/transceiver (UART) or a high-speed serial interface (HSSI), having a speed that is typically between 19.2 kbps to 1 Mbps.

In a system slot (e.g., where the drive sits in a fully functional environment and expected to operate fully, including the standard product interface, and host software stack); firmware is typically required to use the standard product interface, such as serial attached small computer system interface (SAS), serial advanced technology attachment (SATA), or PCIe.

### BRIEF SUMMARY

The embodiments are summarized by the claims that follow below. However, briefly, a system and method for self-testing one or more digital data storage drives are described. In particular, a drive tester system connects to one or more digital data storage drives via a serial two-wire interface, such as a system management bus (SMBus) interface. The drive tester system performs a self-test on the one or more digital data storage drives via the serial two-wire interface. The self-test includes a burn-in and endurance test.

### BRIEF DESCRIPTIONS OF THE DRAWINGS

Various embodiments are illustrated by way of example, and not by way of limitation, in the figures, which are briefly described below.

FIG. 1 is a high-level block diagram of a system for manufacturing and testing drives, such as solid state drives (SSDs) or hard disk drives (HDDs).

FIG. 2 is a conceptual block diagram of a drive tester system, which includes a self-test chamber in this example.

FIG. 3 is an example command set that may be carried out between the host tester system and the one or more drives.

FIG. 4 is a flow chart of an example method for self-testing a digital data storage drive.

FIG. 5 is a block diagram showing a computer apparatus implementation of the host tester system of FIG. 2.

FIG. 6 is a block diagram of a digital data storage drive mounted in a tester system.

It will be recognized that some or all of the Figures are for purposes of illustration and do not necessarily depict the actual relative sizes or locations of the elements shown. The Figures are provided for the purpose of illustrating one or more embodiments with the explicit understanding that they will not be used to limit the scope or the meaning of the claims.

### DETAILED DESCRIPTION

In the following detailed description of the embodiments, numerous specific details are set forth. However, it will be obvious to one skilled in the art that the embodiments may be practiced without these specific details. In other instances well known methods, procedures, components, and circuits have not been described in detail so as not to unnecessarily obscure aspects of the embodiments.

### System Overview

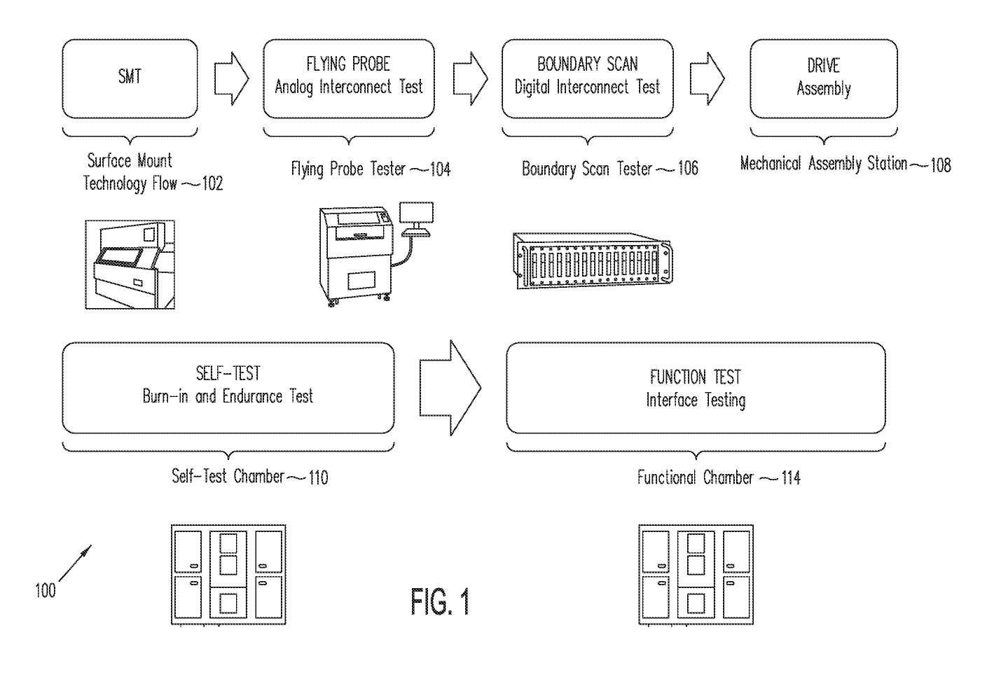

FIG. 1 is a high-level block diagram of a system 100 for manufacturing and testing digital data storage drives, such as solid state drives (SSDs) or hard disk drives (HDDs).

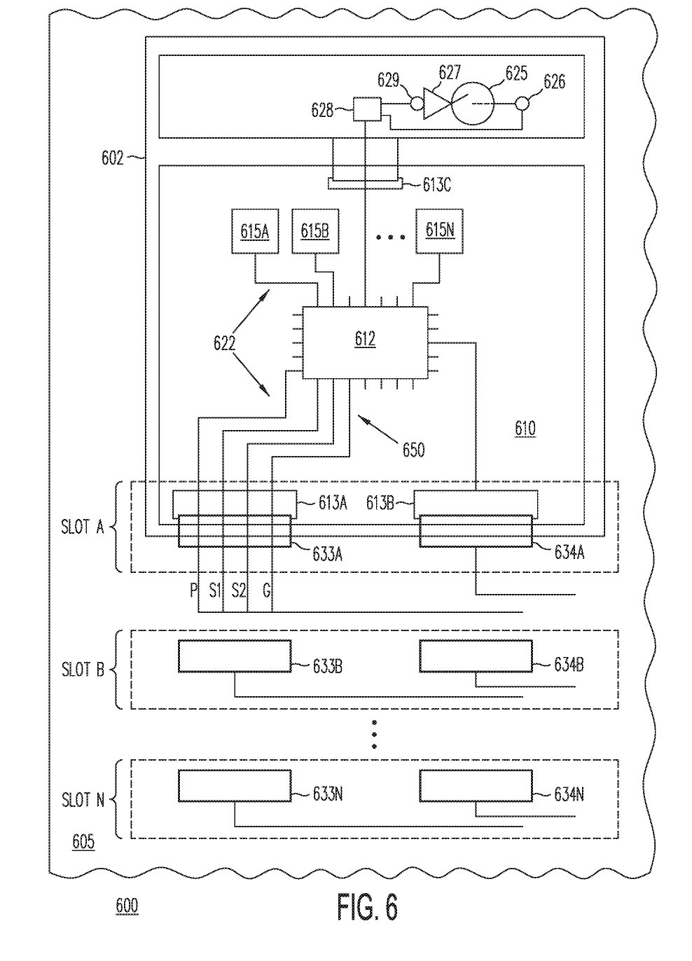

FIG. 6 illustrates a block diagram of a digital data storage drive 602 mounted in a test system 600. The digital data storage drive 602 includes a printed circuit board (PCB) 610 with a controller integrated circuit 612, one or more connectors 613A-613C, and one or more storage integrated circuits 615A-615N mounted to the PCB. The controller integrated circuit 612 and the one or more storage integrated circuits 615A-615N may be surface mounted to the PCB. The printed circuit board 612 includes a plurality of wire traces 622 that electrically couple together the controller integrated circuit 612, the one or more connectors 613A-613C, and the one or more storage integrated circuits 615A-615N.

In the case of a solid state drive, the one or more storage integrated circuits 615A-615N of the digital data storage drive 602 are read-writeable non-volatile memory integrated circuits, such as flash electrically erasable programmable read only memory (EEPROM). In the case of a hard disk drive, the digital data storage drive 602 may further include an electromechanical magnetic disk drive 625, a drive motor 626, read/write heads 627, drive electronic circuit 628 and head motor 629 coupled to the printed circuit board 610 and the controller 612 through the connector 613C.

In any case, it is desirable to test a plurality of digital data storage drives 602 mounted in the test system 600. Accordingly, the test system 600 includes a printed circuit board 605 with a plurality of connectors 633A-633N to interface with the connector 613A of each drive.

Referring now to FIGS. 1 and 6, electronic circuits (e.g., circuit 612, 615A-615N) of digital data storage drives are often manufactured in part with a surface-mount technology (SMT) flow 102. The SMT flow 102, which produces electronic circuits having components that are mounted or placed directly onto the surface of printed circuit (PC) boards (e.g., PCB 610) often with PCB contacts underneath the part. An electronic device so mounted may be referred to as a surface-mount device (SMD). With surface-mount technology (SMT), it may be difficult to access test points for electronic circuits so mounted to fully test each component after mounting.

A flying probe tester 104 is used to test basic production, prototypes, and PC boards that present accessibility problems. The flying probe tester 104 uses electro-mechanically controlled probes to access electronic components mounted on printed circuit assemblies (PCAs). Commonly used for testing analog circuit components, analog signature analysis, and short/open circuits, the flying probe tester 104 can be classified as an in-circuit test (ICT) system or as a Manufacturing Defects Analyzer (MDA).

A boundary scan tester 106 can test interconnects (e.g., nets or wire traces 622, etc.) on printed circuit boards (e.g., PCB 610) between mounted integrated circuits (e.g., integrated circuits 612, 615A-615N) and circuits (e.g., integrated circuit 612) and connectors (e.g., 613A-615C). The boundary scan tester 106 can also test peripheral circuits and input, output, input/output circuit blocks and other functional blocks inside an integrated circuit (e.g., circuits 612, 615A-615N). For example, a boundary scan tester 106 can debug integrated circuit pin states, measure voltage, or analyze sub-blocks inside an integrated circuit. A Joint Test Action Group (JTAG) test interface 650 is the common name for the IEEE 1149.1 Standard Test Access Port and Boundary-Scan Architecture test interface. The JTAG test interface was initially devised by electronic engineers for testing printed circuit boards using boundary scan and is still widely used for this application. The JTAG test interface is also widely used as integrated circuit (IC) debug ports. In the embedded processor market, essentially all modern processors implement a JTAG test interface when they have enough interconnect pins. Since then, this standard has been adopted by electronic device companies all over the world. Boundary scan testing is typically synonymous with a JTAG test interface 650.

With the electrical components initially tested, a mechanical assembly station 108 Is used to assemble one or more of the mechanical components, the electrical components and the electro-mechanical components of a drive together. Solid state drives tend to have fewer mechanical and electro-mechanical components requiring assembly.

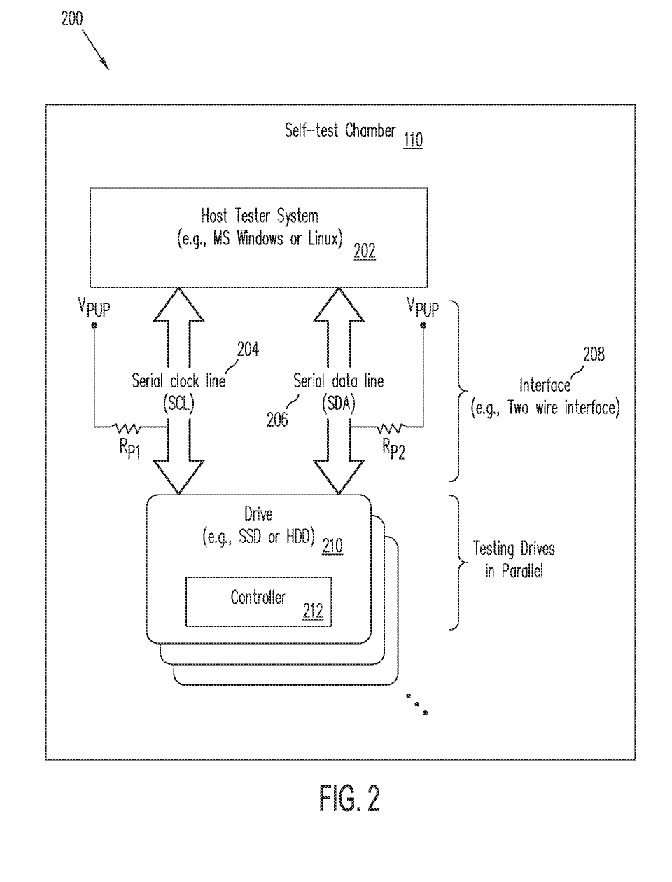

Next, a self-test chamber 110 is used to perform a burn-in and endurance test for one or more storage drives 602. For example, the self-test chamber 110 may be used to perform a built-in self-test (BIST) or built-in test (BIT) on a drive at or above a temperature and a power supply voltage over a period of time. The BIST or BIT is a mechanism or process that permits a drive to test itself. Engineers design BISTs to meet requirements (e.g., high reliability, lower repair cycle times, etc.) or constraints (e.g., limited technician accessibility, cost of testing during manufacture, etc.). BIST can reduce cost in at least two ways: (1) by reducing test-cycle duration and/or (2) reducing the complexity of the test/probe setup, by reducing the number of I/O signals that must be driven/examined under tester control. Both can lead to a reduction in hourly charges of an automated test equipment (ATE) service that would otherwise be used to test a drive. The self-test chamber 110 is further discussed below with reference to FIGS. 2-4.

A burn-in and endurance test for new storage drives provides a stress test (whether highly systematic or less formal) in which the storage drives that are doomed to fail early in life can either do so before the storage drives are in use, or give strong indications that the storage drives will fail in the near future. There are at least two ways to carry out a burn-in and endurance test. In one way, the drive tester system 200 can use a disk utility program or specialized burn-in utility program to run a proprietary heavy-load test on your new drive(s). Such utility programs will either cause a doomed drive to fail, or provide diagnostic feedback that will predict early failure. In another way, the drive tester system 200 can carry out an informal use-specific test. For example, the drive tester system 200 can fill a disk of a storage drive to about 60% capacity, and then create a high track count, edit-dense session with a long duration (e.g., on a digital audio workstation (DAW)). The storage drive(s) are left in a loop playback for 12 or more hours. The storage drive and driver tester system catalogs some important diagnostic information that can help predict early failure of a storage drive.

A functional chamber 114 may then be used to perform a function testing of a storage drive 602 through a storage drive's standard product interface (e.g., serial attached SCSI (SAS) drive interface, serial advanced technology attachment (SATA) drive interface, or peripheral component interconnect-express (PCIe) local computer bus interface) such as may be available at connector 613B. The functional testing of a storage drive is performed on the printed circuit board 610, the electronic circuits 612, 615A-615N mounted thereto, and any electro-mechanical components 625-629 at a board level. Chip level testing of integrated circuit chips 612, 615A-615N is typically performed by a semiconductor manufacturer before receipt and assembly of a storage drive by the storage drive manufacturer. Board level testing of the integrated circuit chips 612, 615A-615N is typically performed with self tests during a self testing mode.

Board-level testing typically uses two test slots (e.g., configurations) to interface to a storage drive: the “full system slot” and the “serial interface slot” (e.g., where the standard interface is not present). The “serial interface slot” is typically more compact and less expensive to produce than the “full system slot”. The “full system slot” requires full standard interface electronics and sufficient computer horse power (e.g., in a full system environment around the drive) to test a storage drive. Using a “full system slot” to test a storage drive is more expensive than using a “serial interface slot”.

The “serial interface slot” has just enough computing power to download, launch, and monitor a storage drive during self-test through a serial interface. Once the drive firmware and self-test code is loaded onto the drive, the drive can proceed with self testing in a self-test mode. Data traffic is limited over the slower serial interface. The data traffic is used to monitor the self-test progress, and to get final test results. During self testing, component functional testing is performed, and NAND flash memory testing and burn-in is performed. Once self-test is complete, the drive can be moved to a “full system slot” to complete drive-level functional testing, interface testing. Drive performance testing is performed (e.g., just enough to establish high-level drive operation). Typically, 80 to 90% of the testing is done in self-test mode in the “serial interface slot”, the remainder being done in the “full system slot”.

Early test processes may have used different stations for firmware download, self-test, and functional testing with different serial interfaces. Another solution for test processes is to use a custom serial interface with a non-standard interface connector. However, a custom connector does not work for PCIe/SFF products with integrated testers. It is desirable to use a single station with “serial interface slot” firmware download during self-test. As further described below, the system carries out testing via a System Management Bus (SMBus).

### Drive Testing via System Management Bus (SMBus) Interface

FIG. 2 is a conceptual block diagram of a drive tester system 200, which includes self-test chamber 110 in this example. Self-test chamber 110 includes (or is connected to) host tester system 202, an interface 208, and at least one digital data storage drive 210. Host tester system 202 is coupled to the one or more drives 210 in slot A through slot N using the interface 208. The interface 208 may be made between connector 613A and 633A shown in FIG. 6. Host tester system 202 may include a general purpose computer (e.g., workstation or desktop computer) having an operating system such as, for example, Microsoft Windows or Linus. Drive 210 is a digital data storage drive that may be implemented, for example, as an SSD or an HDD. In the example of FIG. 2, drive 210 includes a controller 212.

Host tester system 202 can test multiple storage drives 210,602 in parallel over the interface 208, while communicating individually with each drive. If host tester system 202 detects a fault (e.g., short, soldering problem, open circuit, etc.) on one of the multiple drives, then the faulty drive can be removed individually while host tester system 202 continues to test other drives that are not detected to be faulty.

The Interface 208 may include a power line P and a ground line G such as shown in FIG. 6. Data communication over the Interface 208 may include a two wire interface (TWI) and/or a two wire bus, in which two standard wire connections (S1,S2 shown in FIG. 6) couple host tester system 202 to drive 210. In one embodiment, interface 208 includes an Inter-Integrated circuit (I²C) serial computer bus interface, instead of a universal asynchronous receiver/transceiver (UART) interface or a high-speed speed serial interface (HSSI). The Inter-Integrated circuit (I²C) serial computer bus interface uses only two bidirectional serial lines, a Serial Data Line (SDA) 206 and a Serial Clock Line (SCL) 204 (serial lines 51 and S2 shown in FIG. 6) to serially communicate to the circuits coupled to it. The circuits are addressed by an N bit address space (e.g., 7 or 10 bit) for them to receive and act on a command or message. The two-wire lines have pull-up resistors (e.g., Rₚ₁ and Rₚ₂ shown in FIG. 2) to coupled to them and pull up voltages (e.g., Vₚᵤₚ shown in FIG. 2) so that they can be driven by open drain and/or open collector transistor outputs to ground in a wired-OR configuration.

In another embodiment, interface 208 includes a system management bus (SMBus) interface, instead of a Universal Asynchronous Receiver/Transmitter (UART) or a High-Speed Serial Interface (HSSI). SMBus is a two-wire data connection having SMBDAT and SMBCLK lines (e.g., serial S1 and S2). The two-wire lines have pull-up resistors coupled to them so that they can be driven by open drain and/or open collector transistor outputs to ground in a wired-OR configuration. SMBus is a subset of I²C that defines communication protocols and signal timing/frequency a little more strictly. One purpose of SMBus is to promote robustness and interoperability between electronic circuits (e.g., circuits 612, 615A-615N). Accordingly, a modern I²C interface incorporates policies and rules from SMBus, sometimes supporting both I²C and SMBus, requiring only minimal reconfiguration to support either or both.

In one embodiment, the host tester system 202 uses an SMBus interface and/or I²C interface directly as a medium-speed serial interface. Accordingly, the interface 208 can easily perform all the duties of UART or HSSI. Further, SMBus and/or I²C has the ability to address different port locations and issue different commands to the drive 210,602. Accordingly, the different ports and commands enable much more functionality and flexibility to drive-level testing of the storage drive (as compared to UART or HSSI). The additional functionality and flexibility is apparent during component testing of drive 210, even before the system has installed product firmware into the drive 210,602. Thus, using SMBus and/or PC provides a broad range of capabilities more than using UART.

To handle a PCIe protocol or a non-volatile memory express (NVMe) protocol, pins for an SMBus interface are already allocated on a standard connector for those protocols. For example, the host tester system 202 may use a standard Edge Card connector or a standard small form factor (SFF) connector to read vital product data (VPD) from the storage drive 210.

For other interface protocols (e.g., Advanced Host Controller Interface (AHCI), proprietary PCIe, SCSI, SAS, or SATA), host tester system 202 uses reserved pins for multiplexing of already-used pins. However, after the host tester system 202 establishes a mechanical and electrical interconnect to drive 210, the host tester system 202 can use any of these protocols and often on the same slot (e.g., slot A shown in FIG. 6). The host tester system 202 can then use generic test code, generic sequence, and/or generic software. Accordingly, the host tester system 202 can bypass a custom front-end interface portion of the storage drive 210. Such ability to bypass enables more commonality of host tester resources for software development and/or for useable code.

The controller 212 of the storage drive can port the SMBus protocol and/or I²C protocol between the host tester system 202 and the storage drive 210. The controller 212 may be any suitable general purpose microcontroller (e.g., Texas Instruments MSP430 microcontroller). In another embodiment (not shown), the controller 210 is integrated into a system on chip (SoC) and uses one or more processors on the SoC. The SoC includes the necessary hardware and electronic circuitry for a complete computing system. For example, an SoC includes on-chip memory (RAM and ROM), the microprocessor, peripheral interfaces, I/O logic control, data converters, and other components that comprise a complete computer system.

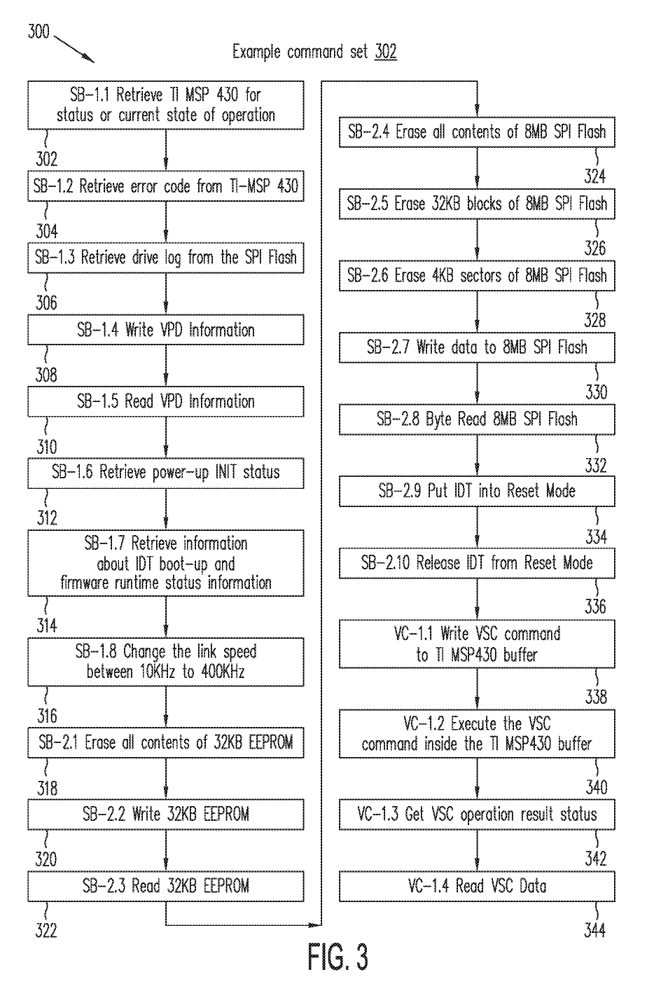

Referring now to FIG. 3, an example testing command set 302 is shown that may be carried out between host tester system 202 and the storage drive 210 of FIG. 2. The example testing command set 302 includes commands that can be carried over an SMBus and/or PC bus to issue a self-test on one or more storage drives 210.

At command 302, the host tester system 202 retrieves the “TI MSP 430” for status or current state of operation of the drive 210. TI MSP 430 is a model of a Texas Instruments mixed signal processor.

At command 304, the host tester system 202 retrieves an error code from the TI MSP 430. At command 306, the host tester system 202 retrieves the drive log from serial peripheral interface (SPI) flash memory. At command 308, the host tester system 202 writes vital product data (VPD) information. At command 310, the host tester system 202 reads VPD information. At command 312, the host tester system 202 retrieves a power-up initialization (INIT) status. At command 314, the host tester system 202 retrieves information integrated device technology (IDT) boot-up and firmware runtime status information. At command 316, the host tester system 202 changes the link speed between 10 kilohertz and 400 kilohertz.

At command 318, the host tester system 202 erases all contents of electrically erasable programmable read-only memory (EEPROM), which is 32 kilobytes in this example. At command 320, the host tester system 202, writes to the EEPROM. At command 322, the host tester system 202 reads from the EEPROM.

At command 324, the host tester system 202 erases all contents of serial peripheral interface (SPI) flash memory, which is 8 megabytes in this example. At command 326, the host tester system 202 erases 32-kilobyte blocks of the SPI flash memory. At command 328, the host tester system 202 erases 4 kilobyte sectors of the SPI flash memory. At command 330, the host tester system 202 writes data to the SPI flash memory. At command 332, the host tester system 202 reads bytes of data from the SPI flash memory.

At command 334, the host tester system 202 puts the information device technology (IDT) into reset mode. At command 336, the host tester system 202 releases the IDT from reset mode. At command 338, the host tester system 202 writes the vendor specific command (VSC) to the TI MSP 430 buffer. At command 340, the host tester system 202 executes the VSC inside the TI MSP 430 buffer. At command 342, the host tester system 202 gets a VSC operation result status. At command 344, the host tester system 202 reads the VSC data.

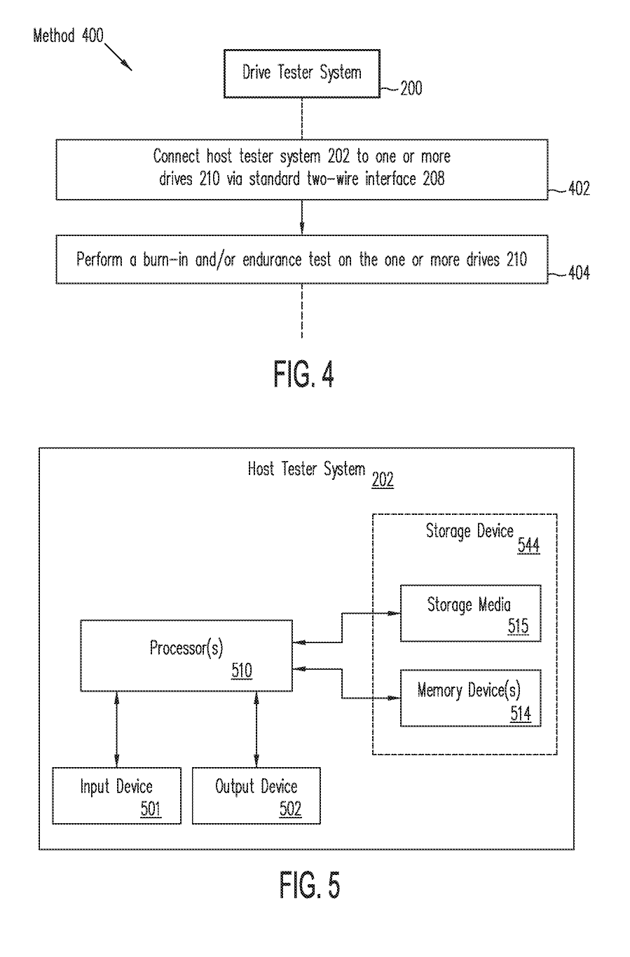

Referring now to FIG. 4, a flow chart of an example method 400 for self-testing a digital data storage drive is illustrated. In one embodiment, the drive tester system 200 of FIG. 2 can carry out the example self testing method 400.

At action 402, one or more drives 210 are coupled to the host tester system 202 in the drive tester system 200 via a standard two-wire interface 208. As described above, the interface 208 may include an I²C interface and/or an SMBus interface.

At action 404, the drive tester system 200 initiates a self-test in the one or more drives 210 via the interface 208. The self-tests performed on each drive 210 may include, for example, a burn-in and endurance test as described above with reference to FIG. 1.

Other actions and/or details that are discussed with reference to other figures and may be a part of the method 400, depending on the implementation.

### Computer Apparatus

FIG. 5 is a block diagram showing a computer apparatus implementation of the host tester system 202 shown in FIG. 2. The host tester system 202 may be implemented in part by a desktop computer, a workstation, or a laptop computer, among other devices.

In the example of FIG. 5, the host tester system 202 includes an input device 501 (e.g., keyboard, mouse, Ethernet or other communications port), an output device 502 (e.g., monitor, speakers, printer, communications port, or a writeable media drive), one or more processors 510, and a storage device 544 coupled together as shown. The storage device 544 may include storage media 515 and one or more memory devices 514 (e.g., ROM, RAM, EEPROM, flash memory and/or other memory building blocks). The storage media 515 is configured to store data in a non-volatile manner such as in a non-volatile memory, a hard disk drive, a solid-state drive, and the like. In some embodiments, as is known in the art, storage media 515 may be located on another computing device across a network. Instructions may be loaded from storage media 544 into the one or more memory devices 514. The one or more processors 510 may retrieve instructions from the storage media 515 or the one or more memory devices 514 and execute the instructions to perform the operations described herein.

Included in the one or more memory devices 514 or storage media 515 is a set of processor executable instructions that, when executed by the one or more processors 510 configures the computing apparatus to control the host tester system 202 in a manner consistent with the methods disclosed herein. A user interface for controlling the host tester system 202 may be displayed by the output device 502 in response to processor or machine readable instructions.

The one or more processors 510 execute instructions stored in a non-transitory machine-readable memory or storage device, such as the one or more memory devices 514, the storage media 544, or a removable storage device (e.g., at least one of an optical medium, a compact disk (CD), a digital video disk (DVD), a magnetic medium, magnetic disk, or a magnetic tape, etc.).

When implemented in software, the elements of the embodiments of the invention are essentially the program, code segments, or instructions to perform the necessary tasks. The program, code segments, or instructions can be stored in a processor readable medium or storage device that can be read and executed by a processor. The processor readable medium may include any medium that can store information. Examples of the processor readable medium include, without limitation, an electronic circuit, a semiconductor memory device, a read only memory (ROM), a flash memory, an erasable programmable read only memory (EPROM), a floppy diskette, a CD-ROM, an optical disk, and a magnetic disk. The program or code segments may be downloaded via computer networks such as the Internet, Intranet, etc. and stored in the processor readable medium or storage device.

Some portions of the preceding detailed description may have been presented in terms of algorithms and symbolic representations that perform operations on data bits within a computer memory. These algorithmic descriptions and representations are the tools used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities may take the form of electrical (e.g., current or voltage) or magnetic signals capable of being stored, transferred, combined, compared, and otherwise manipulated. It has proven convenient at times, principally for reasons of common usage, to refer to these signals as bits, values, levels, elements, symbols, characters, terms, numbers, or the like.

However, that all of these and similar terms are to be associated with the appropriate physical quantities and are merely convenient labels applied to these quantities. Unless specifically stated otherwise as apparent from the above discussion, it is appreciated that throughout the description, discussions utilizing terms such as “processing” or “computing” or “calculating” or “determining” or “displaying” or the like, refer to the action and processes of a computer system, processing logic, or similar electronic computing device, that automatically or semi-automatically manipulates and transforms data represented as physical (electronic) quantities within the computer system's registers and memories into other data similarly represented as physical quantities within the computer system memories or registers or other such information storage, transmission or display devices.

Additionally, the embodiments of the invention are not described with reference to any particular programming language. It will be appreciated that a variety of programming languages may be used to implement the teachings of the embodiments of the invention as described herein.

### Conclusion

A system and method for self-testing one or more digital data storage drives are described. In particular, a drive tester system connects to the one or more digital data storage drives via a standard two-wire interface, such as a system management bus (SMBus) interface. The drive tester system performs a self-test on the one more digital data storage drives via the standard two-wire interface. The self-test includes a burn-in and endurance test.

It will be appreciated that the embodiments of the invention can be practiced by other means than that of the above-described embodiments, which are presented in this description for purposes of illustration and not of limitation. The specification and drawings are not intended to limit the exclusionary scope of this patent document. It is noted that various equivalents for the particular embodiments discussed in this description may be practice by the claimed invention as well. That is, while specific embodiments of the invention have been described, it is evident that many alternatives, modifications, permutations and variations will become apparent in light of the foregoing description. Accordingly, it is intended that the claimed invention embrace all such alternatives, modifications and variations as fall within the scope of the appended claims. The fact that a product, process, or method exhibits differences from one or more of the above-described exemplary embodiments does not mean that the product or process is outside the scope (literal scope and/or other legally-recognized scope) of the following claims.

What is claimed is:

1. A drive tester system, comprising:
one or more digital data storage drives;
one or more interfaces each having two standard wire connections; and
a self-test chamber coupled to the one or more digital data storage drives via the one or more interfaces, the self-test chamber configured to carry out a self-test on the one or more digital data storage drives via the one or more interfaces, wherein the self-test includes a burn-in and endurance test and wherein the one or more digital data storage drives are coupled to the self-test chamber during the self-test without disconnection from the one or more interfaces.

2. The drive tester system of claim 1, wherein the one or more digital data storage drives are solid state drives.

3. The drive tester system of claim 1, wherein the one or more digital data storage drives are hard disk drives.

4. The drive tester system of claim 1, wherein the two standard wire connections of each of the one or more interfaces include a serial clock line (SCL) and a serial data line (SDA).

5. The drive tester system of claim 1, wherein the one or more interfaces include a system management bus (SMBus) interface.

6. The drive tester system of claim 1, wherein the one or more interfaces include an Inter-Integrated Circuit (I²C) bus interface.

7. The drive tester system of claim 1, wherein each of the one or more digital data storage drives includes a controller that is configured to communicate with at least one of:
an SMBus protocol; or
an I²C protocol.

8. The drive tester system of claim 7, wherein the controller includes a general purpose microcontroller.

9. The drive tester system of claim 7, wherein the controller is integrated into a system on chip (SoC) including one or more processors.

10. The drive tester system of claim 1, wherein the one or more interfaces do not include a universal asynchronous/transceiver (UART) or a high-speed interface (HSSI).

11. The drive tester system of claim 1, wherein
the one or more digital data storage drives are a plurality of digital data storage drives; and
the self-test chamber is further configured to test the plurality of digital data storage drives in parallel over the one or more interfaces.

12. The drive tester system of claim 1, wherein
each two standard wire connections are coupled to two sets of a pull-up resistor coupled to a pull-up voltage.

13. A method for self-testing a digital data storage drive, the method comprising:
forming a connection between a self-test chamber and the digital data storage drive via a standard two-wire interface;
performing a self-test on the digital data storage drive via the standard two-wire interface, wherein the self-test includes a burn-in and endurance test, and
maintaining the connection between the self-test chamber and the digital storage drive during the self-test.

14. The method of claim 13, wherein the digital data storage drive is a solid state drive.

15. The method of claim 13, wherein the digital data storage drive is a hard disk drive.

16. The method of claim 13, wherein the digital data storage drive is a hybrid disk drive including a magnetic disk of a hard disk drive and electrically erasable programmable read only memory of a solid state drive.

17. The method of claim 13, wherein the two standard wire connections include a serial clock line (SCL) and a serial data line (SDA).

18. The method of claim 13, wherein the interface includes a system management bus (SMBus) interface.

19. The method of claim 13, wherein the interface includes an Inter-Integrated Circuit (I²C) bus interface.

20. The method of claim 13, wherein the digital data storage drive includes a controller that is configured to port at least one of: a system management bus (SMBus) protocol; or an Inter-Integrated circuit (I²C) protocol.

21. The method of claim 20, wherein the controller includes a general purpose microcontroller.

22. The method of claim 19, wherein the controller is integrated into a system on chip (SoC) comprising one or more processors.
